(19) United States
(12) Patent Application Publication
(10) Pub. No.: US 2025/0298316 A1
(43) Pub. Date: Sep. 25, 2025

(54) AUTOCATALYTIC ACID AMPLIFICATION FOR PHOTOSELECTIVE ACID DIFFUSION

(71) Applicant: Tokyo Electron Limited, Tokyo (JP)

(72) Inventors: Michael Murphy, Albany, NY (US); Jodi Grzeskowiak, Schenectady, NY (US); David Conklin, Saratoga Springs, NY (US)

(21) Appl. No.: 18/611,518

(22) Filed: Mar. 20, 2024

(51) Int. Cl. G03F 7/11; G03F 7/00; G03F 7/004; G03F 7/16; G03F 7/20

(52) U.S. Cl. CPC G03F 7/11; G03F 7/0035; G03F 7/0045; G03F 7/161; G03F 7/162; G03F 7/2004

(57) ABSTRACT

An embodiment method of processing a substrate includes the patterning a photoresist layer formed over the substrate using a photolithographic technique, and spin coating a first overcoat material over the patterned photoresist layer, where the first overcoat material includes a photo-acid generator (PAG) and an acid amplifier (AA). The method includes exposing the first overcoat material to an ultraviolet (UV) irradiation to generate first acid from the PAG, where the first acid decomposes the AA to generate second acid, and a total amount of the second acid generated from the decomposition of the AA being greater than a total amount of first acid generated from the PAG. The method includes diffusing the second acid into a portion of the patterned photoresist layer, where the diffused second acid changes a solubility of the portion such that the portion becomes soluble in a developing solution.

### TECHNICAL FIELD

The present invention relates generally to methods of processing a substrate, and, in particular embodiments, to autocatalytic acid amplification for photoselective acid diffusion.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning at nanoscale features.

### SUMMARY

In accordance with an embodiment, a method of processing a substrate includes the patterning a photoresist layer formed over the substrate using a photolithographic technique, and spin coating a first overcoat material over the patterned photoresist layer, where the first overcoat material includes a photo-acid generator (PAG) and an acid amplifier (AA). The method includes exposing the first overcoat material to an ultraviolet (UV) irradiation to generate first acid from the PAG, where the first acid decomposes the AA to generate second acid, and a total amount of the second acid generated from the decomposition of the AA being greater than a total amount of first acid generated from the PAG. The method includes diffusing the second acid into a portion of the patterned photoresist layer, where the diffused second acid changes a solubility of the portion such that the portion becomes soluble in a developing solution.

In accordance with an embodiment, a method of patterning includes forming a mandrel over a substrate, and depositing a first overcoat material over the mandrel. The first overcoat material includes an acid-generator (AG) and an acid amplifier (AA), where a concentration of the AA is greater than that of the AG. The method includes generating first acid from the AG, the first acid catalyzing a formation of second acid from the AA, the second acid diffusing into a portion of the mandrel. The method includes selectively removing the first overcoat material, and depositing a second overcoat material over the mandrel, and forming two antispacers from the mandrel by selectively removing the portion of the mandrel, where each antispacer is formed on each sidewall of the mandrel, the antispacers separating the mandrel and the second overcoat material.

In accordance with an embodiment, a method of processing a substrate includes patterning a photoresist layer formed over the substrate using a deep ultraviolet (DUV) photolithographic technique; and spin coating a first overcoat material over the patterned photoresist layer, where the first overcoat material includes a photo-acid generator (PAG) and an acid amplifier (AA). The method includes exposing the first overcoat material to an ultraviolet (UV) irradiation to generate first acid from the PAG, the first acid decomposing the AA to generate second acid, where the second acid diffuses into a portion of the patterned photoresist layer. The method includes selectively removing the first overcoat material, spin coating a second overcoat material over the patterned photoresist layer, etching back the second overcoat material to expose a top surface of the patterned photoresist layer, and selectively dissolving and removing the portion of the patterned photoresist layer using a developing solution to form a relief pattern that has a pitch size below an optical resolution of the DUV photolithographic technique.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1N illustrate a substrate at different stages of a method of forming sub-resolution features comprising antispacer patterning in accordance with various embodiments, wherein FIG. 1A illustrates a cross-sectional view of an incoming substrate comprising photoresist mandrels, FIG. 1B illustrates a top view of FIG. 1A, FIG. 1C illustrates a cross-sectional view of the substrate after depositing a first overcoat comprising a photo-acid generator (PAG) and an acid amplifier (AA), FIG. 1D illustrates a top view of FIG. 1C, FIG. 1E illustrates a cross-sectional view of the substrate after an exposure to an actinic radiation, FIG. 1F illustrates a top view of FIG. 1E, FIG. 1G illustrates a cross-sectional view of the substrate after removing the first overcoat, FIG. 1H illustrates a top view of FIG. 1G, FIG. 1I illustrates a cross-sectional view of the substrate after depositing a second overcoat, FIG. 1J illustrates a top view of FIG. 1I, FIG. 1K illustrates a cross-sectional view of the substrate after a development step, FIG. 1L illustrates a top view of FIG. 1K, FIG. 1M illustrates a cross-sectional view of the substrate after a pattern transfer, and FIG. 1N illustrates a top view of FIG. 1M;

FIG. 2 illustrates a top view of another substrate after the exposure to the actinic radiation and removing the first overcoat in accordance with alternate embodiments;

FIG. 3 illustrates the effect of the presence of an acid amplifier (AA) in an overcoat on the development after a low-dose ultraviolet (UV) irradiation;

FIG. 4 illustrates the removal of a photoresist film as a function of exposure dose;

FIG. 5 illustrates the solubility of a photoresist film as a function of the degree of acid deprotection controlled by exposure dose; and

FIG. 6A-6C illustrate process flow charts of methods of sub-resolution features comprising antispacer patterning in accordance with various embodiments, wherein FIG. 6A illustrates one embodiment, FIG. 6B illustrates another embodiment, and FIG. 6C illustrates yet another embodiment.

### DETAILED DESCRIPTION OF ILLUSTRATIVE EMBODIMENTS

This application relates to methods of processing a substrate, and, in particular embodiments, to the process of antispacer double patterning that uses chemically amplified photoresists (CAR). Various embodiments use autocatalytic acid amplification in the overcoat for photoselective acid diffusion, which may advantageously improve the tonality of the process.

Chemically amplified photoresists (CAR) have been ubiquitous within the semiconductor industry since the adoption of 248 nm lithography. The primary patterning mechanism is locational generation of acid through exposure to radiation and subsequent deprotection of a polymer resin(s) to enable a solubility shift. In recent years, advanced technology nodes have required ever more stringent performance metrics that have inspired new processes to complement standard resist patterning post-develop. Double patterning is an effective technique to form sub-resolution features (i.e., pitch size below the optical resolution of a photolithographic technique applied), where two spacers or antispacers are formed from one mandrel. In antispacer double patterning, the pitch doubling is enabled through acid diffusion across the photoresist-overcoat interface enabling selective deprotection aligned to the resist mandrel to form narrow trenches defined by the acid diffusion length. Acid diffusion into the photoresist from a surrounding overcoat may be controlled locationally across the substrate through the selective decomposition of acid generators. Current photoselective antispacer technology seeks to generate majority acid concentration within an overcoat by exposure to radiation. However, the impinging light will also react with the underlying photoresist mandrel causing unwanted acid generation throughout. A tradeoff will exist, narrowing the process window, to generate the appropriate acid concentration within the overcoat to define the antispacer trench versus minimizing deprotection throughout the photoresist mandrel that may lead to uncontrolled dissolution. Therefore, it is desired to develop a new antispacer double patterning technique that can prevent the dissolution of the photoresist mandrel.

The method of antispacer double patterning in this disclosure aims to minimize exposure dose while maximizing acid production within an overcoat to prevent the complete dissolution of the photoresist mandrel through internally generated acid. In various embodiments, the overcoat may be designed to incorporate reagents capable of autocatalytic decomposition to form acid known as acid amplifiers (AA). Standard overcoat formulations designed to trim the critical dimensions (CD) of a photoresist mandrel through external diffusion of acid often are composed of either free acid or a photo-acid generator (PAG). The use of free-acid results in no locational selectivity for diffusion to occur. The sole use of PAG within the overcoat formulation requires significant exposure dose to uniformly generate acid to the required concentration which may result in undesired reactions within the photoresist mandrel as stated above.

The incorporation of both PAG and AA allow for a minimal exposure dose (e.g., <10 mJ/cm²) to generate PAG acid which in turn will initiate the autocatalytic decomposition of the surrounding AA molecules. Compared to a typical overcoat containing only PAG, a fraction of the exposure dose is required to generate large quantities of acid within the PAG+AA system, thereby minimizing the PAG decomposition occurring within the photoresist mandrel.

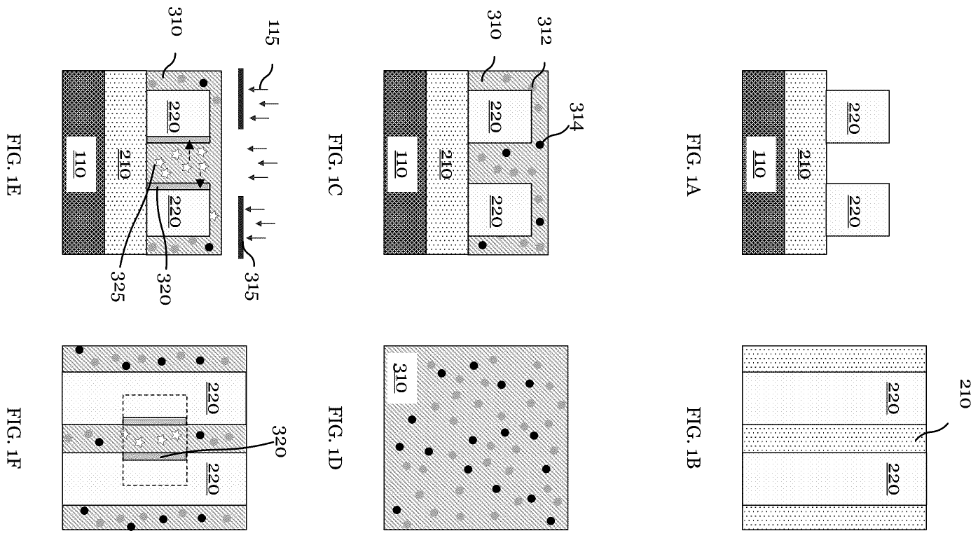

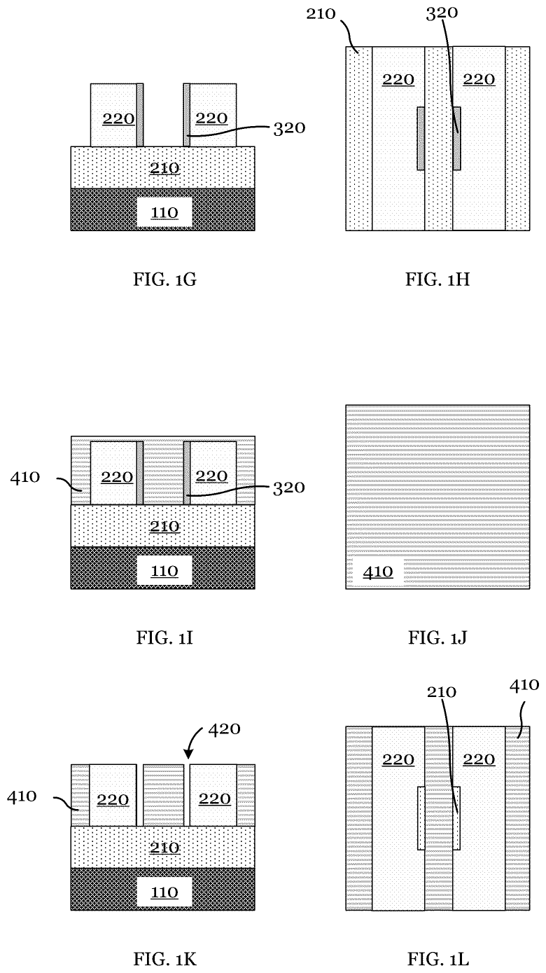

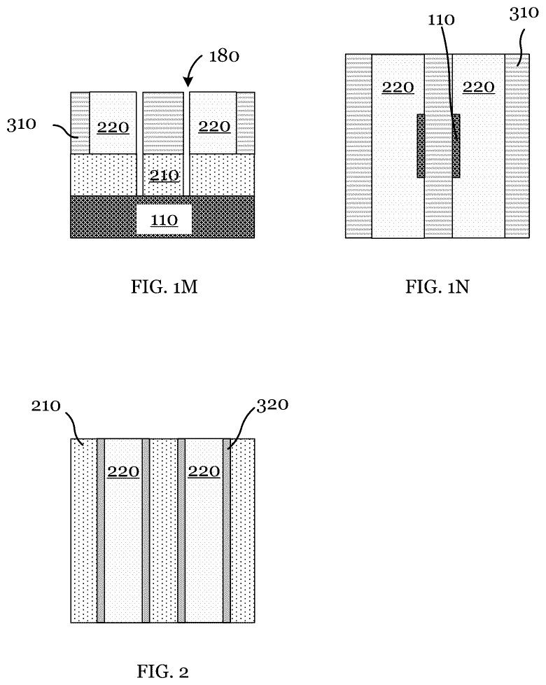

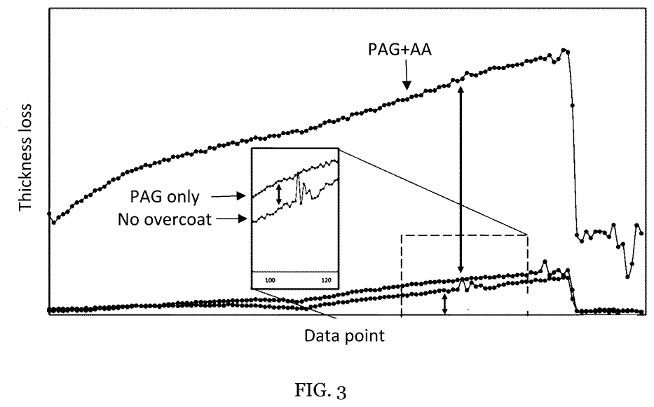

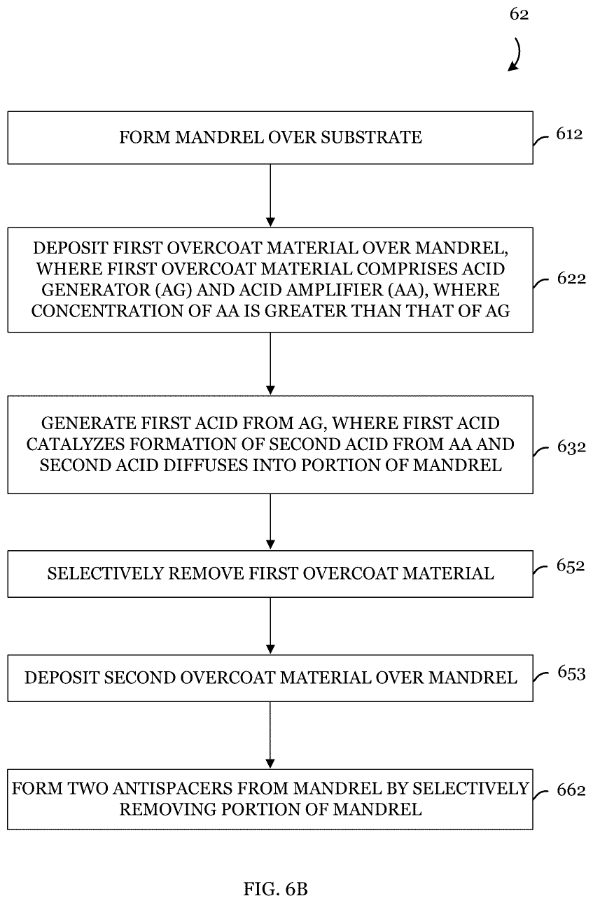

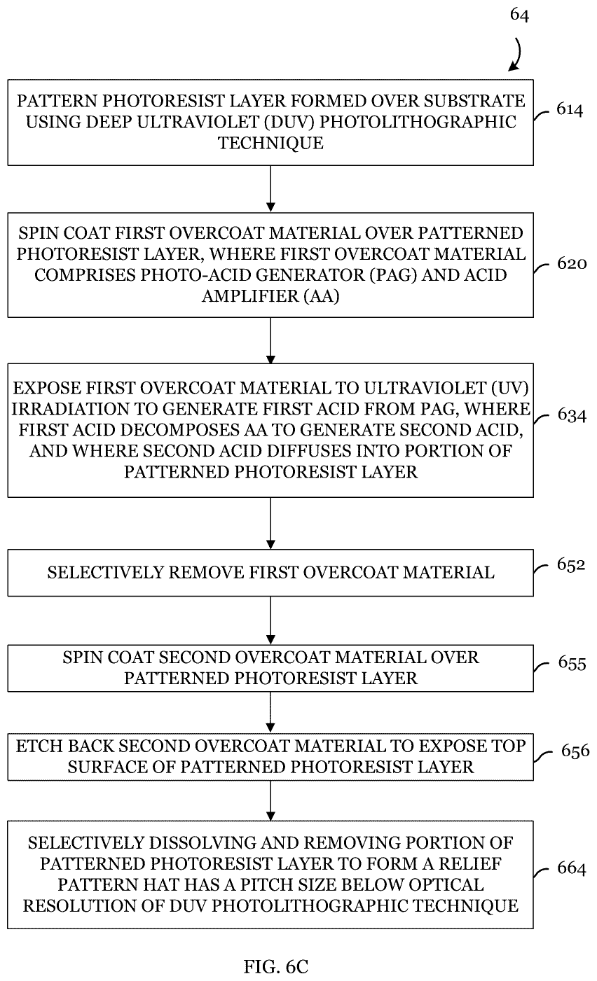

In the following, a process of antispacer double patterning to form sub-resolution features is described referring to FIGS. 1A-1N. An alternate embodiment with a blanket exposure to form long trench features is described referring to FIG. 2. The critical role of the addition of AA to the overcoat to enable antispacer patterning with the low-dose exposure is demonstrated with experimental data presented in FIGS. 3-5. Several embodiment process flows of antispacer patterning are described referring to FIGS. 6A-6C. All Figures in the disclosure, including the aspect ratios of features, are not to scale and for illustration purposes only.

In this disclosure, sacrificial structures adjacent to the photoresist mandrel used to form trenches or any recesses are referred to as “antispacers.” Further, any list that presents possible compositions, conditions, or process variations includes any reasonable combination thereof, and thus the term “or” used in the list does not indicate any exclusive selection of a particular composition, condition, or process variation.

FIGS. 1A-1N illustrate a substrate at different stages of a method of forming sub-resolution features comprising antispacer patterning in accordance with various embodiments.

FIG. 1A illustrates a cross-sectional view of an incoming substrate 110 comprising photoresist mandrels 220, and FIG. 1B illustrates a corresponding top view of the substrate 110.

The substrate 110 may be a part of, or include, a semiconductor device, and may have undergone a number of steps of processing following, for example, a conventional process. The substrate 110 accordingly may comprise layers of semiconductors useful in various microelectronics. For example, the semiconductor structure may comprise the substrate 110 in which various device regions are formed.

In one or more embodiments, the substrate 110 may be a silicon wafer, or a silicon-on-insulator (SOI) wafer. In certain embodiments, the substrate 110 may comprise a silicon germanium wafer, silicon carbide wafer, gallium arsenide wafer, gallium nitride wafer and other compound semiconductors. In other embodiments, the substrate 110 comprises heterogeneous layers such as silicon germanium on silicon, gallium nitride on silicon, silicon carbon on silicon, as well layers of silicon on a silicon or SOI substrate. In various embodiments, the substrate 110 is patterned or embedded in other components of the semiconductor device.

The semiconductor structure may have undergone a number of steps of processing following, for example, a conventional process. For example, the semiconductor structure may comprise a substrate 110 in which various device regions are formed. At this stage, the substrate 110 may include isolation regions such as shallow trench isolation (STI) regions as well as other regions formed therein.

In FIGS. 1A and 1B, the substrate 110 may comprise an intermediate layer 210 formed over the substrate 110. The intermediate layer 210 may be a target for pattern transfer in subsequent processing after the antispacer patterning. In various embodiments, the intermediate layer 210 may comprise silicon, silicon oxynitride, organic material, non-organic material, or amorphous carbon. In certain embodiments, the intermediate layer 210 may also be selected to have anti-reflective properties such as by using a silicon bottom anti-reflective coating (Si-BARC). In one or more embodiments, the intermediate layer 210 may be a mask layer comprising a hard mask. The hard mask may comprise silicon nitride, silicon dioxide (SiO₂), or titanium nitride. Further, the intermediate layer 210 may be a stacked hard mask comprising, for example, two or more layers using two different materials. A first layer of the hard mask may comprise a metal-based layer such as titanium nitride, titanium, tantalum nitride, tantalum, tungsten based compounds, ruthenium based compounds, or aluminum based compounds, and a second layer of the hard mask may comprise a dielectric layer such as silicon dioxide, silicon nitride, silicon oxynitride, silicon carbide, amorphous silicon, or polycrystalline silicon. The intermediate layer 210 may be deposited using deposition techniques such as vapor deposition including chemical vapor deposition (CVD), physical vapor deposition (PVD), and atomic layer deposition (ALD), as well as other plasma processes such as plasma enhanced CVD (PECVD), sputtering, and other processes.

Still referring to FIGS. 1A and 1B, photoresist mandrels 220 may be formed over the intermediate layer 210. The photoresist mandrels 220 may be a patterned photoresist, which may be formed by conventional methods. In certain embodiments, a layer of a photoresist may be deposited over the intermediate layer 210, e.g., using a coating process or a spin-on process. In various embodiments, the photoresist may comprise a light sensitive organic material, and may be applied from a solution by, for example, a conventional spin coating technique. In some embodiments, the photoresist may comprise a positive tone resist or alternatively a negative tone resist. In various embodiments, the photoresist may comprise a solubility-changing agent necessary for the initial patterning of forming the mandrel. The solubility-changing agent may comprise a photo-acid generator (PAG).

In various embodiments, a conventional photolithographic process (e.g., soft bake, actinic radiation exposure, post-exposure bake, and development) may be used to pattern the photoresist. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology. Additionally, the photolithography technology may be mask-based (e.g., projection lithography), maskless (e.g., e-beam lithography), or another suitable type of lithography. In one or more embodiments, deep ultraviolet (DUV) and/or immersion lithography may be used. As described below in various embodiments, antispacer patterning enables forming features having a pitch size below the optical resolution of the photolithographic technique used to form the photoresist mandrels 220. In one embodiment, a post-exposure bake may be performed by thermally treating the substrate 110, for example, at 60-140° C. The developing step may be performed by a conventional developing method. In various embodiments, the developing solution may comprise a metal iron free (MIF) developer, for example, an aqueous solution of tetramethylammonium hydroxide (TMAH). In other embodiments, the developing solution may comprise a metal ion containing developer, for example, an aqueous solution of sodium hydroxide (NaOH) or potassium hydroxide (KOH). As a result, a pattern of the photoresist (e.g., lines in FIG. 1B) is formed over the intermediate layer 210 as the photoresist mandrels 220.

The photoresist mandrels 220 may have any suitable thickness, which also may be referred to as height. In certain embodiments, the photoresist mandrels 220 have a thickness of 5 nm to 5 μm, for example 20 nm to 1 μm. Further, the critical dimension (CD) of the photoresist mandrel 220 may be any size enabled by the photolithographic technique applied. In one embodiment, the CD may be 200 nm or less. The photoresist mandrels 220 define the first relief pattern where antispacers may be formed for double patterning. Various embodiments of the methods reduce the CD of the first relief pattern through antispacer patterning, and forms smaller features, for example, with a CD less than 100 nm, and thereby enable pitch doubling.

FIG. 1C illustrates a cross-sectional view of the substrate 110 after depositing a first overcoat 310 comprising a photo-acid generator (PAG) and an acid amplifier (AA), and FIG. 1D illustrates a corresponding top view of the substrate 110.

In various embodiments, the PAG may be ionic or non-ionic PAG. For example, ionic PAGs may include triphenylsulfonium triflate and Bis(4-tert-butylphenyl)iodonium triflate, while non-ionic PAGs may include N-Hydroxynaphthalimide triflate and N-Hydroxy-5-norbomene-2,3-dicarboximide perfluoro-1-butanesulfonate.

In FIGS. 1C and 1D, the first overcoat 310 is deposited as an overcoat material over the substrate 110, covering the photoresist mandrel 220. In various embodiments, the first overcoat 310 may be deposited using a coating process or a spin-on process. In FIGS. 1C and 1D, the first overcoat 310 covers the top surface of the photoresist mandrel 220 in addition to their sidewalls. The spin speed may be controlled to reduce the thickness of the first overcoat 310 extending above the top surface of the photoresist mandrel 220 in some embodiments. In various embodiments, the first overcoat 310 may comprise a photo-acid generator (PAG) 312 and an acid amplifier (AA) 314, and have a different composition from the photoresist mandrel 220.

In various embodiments, the AA 314 may be characterized by the ability to be decomposed via acid-catalyzed mechanisms and to produce more acid. In certain embodiments, the AA 314 may produce acid that is strong enough to catalyze its decomposition, which means the AA decomposition occurs autocatalytically once the initial catalytic acid triggers the decomposition. Examples of the AA 314 may include, but are not limited to, sulfonates that can produce fluorinated sulfonic acids upon decomposition. For example, in one or more embodiments, AA 314 may include 3-hydroxy-3-methylbutyl 4-methylbenzenesulfonate, 3-Hydroxy-3-methylbutyl 4-(trifluoromethyl)benzenesulfonate and 3-Hydroxybutyl 4-(trifluoromethyl)benzenesulfonate. Several factors may be considered when selecting a suitable material for the AA 314 such as the thermal stability of the AA, the turnover number of the AA, and the acidity/diffusivity of the acid produced, and others.

The autocatalytic acid amplification by the AA 314 can reduce the required amount of the PAG 312 in the first overcoat 310 to generate an amount of acid necessary for acid diffusion and antispacer patterning. The inventors of this application identified that the use of lower amount of PAG in the first overcoat 310 may in turn enable the antispacer patterning with low dose exposure. Accordingly, in various embodiments, the PAG concentration in the first overcoat 310 may be substantially lower than the AA concentration. In one embodiment, the first overcoat 310 may contain 0.1-4.0 wt % PAG and 1.0-20 wt % AA.

Although the first overcoat 310 is illustrated as a single layer with a substantially uniform distribution of both the PAG 312 and the AA 314 in FIGS. 1C and 1D, in other embodiments, more than one material layer may be used for the first overcoat 310. In various embodiments, it would be advantageous to increase PAG concentration to increase the potential homogeneity of acid generation among the AA molecules so that a pocket of higher acid concentration across wafer or across macro does not exist.

In certain embodiments, an overcoat bake treatment may be performed after depositing the first overcoat 310 and prior to a subsequent exposure step (e.g., FIGS. 1E and 1F). In one embodiment, the overcoat bake may be performed by thermally treating the substrate 110, for example, at 80-140° C.

FIG. 1E illustrates a cross-sectional view of the substrate 110 after an exposure to an actinic radiation, and FIG. 1F illustrates a corresponding top view of the substrate 110.

In FIGS. 1E and 1F, the exposure step may be performed by exposing the substrate to an actinic radiation 115 using a photomask 315. In another embodiment, a blanket exposure without a photomask may be used as described in a later section referring to FIG. 2. In various embodiments, the photomask 315 may have holes or square openings to define the area of antispacers. For example, in FIG. 1F, an area within a dotted square may be the opening of the photomask 315.

In various embodiments, the exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), EUV lithography, DUV lithography, or any suitable photolithography technology. Additionally, the photolithography technology may be mask-based (e.g., projection lithography), maskless (e.g., e-beam lithography), or another suitable type of lithography. In one embodiment, the 266 nm UV may be used. In various embodiments, an exposure dose is substantially lower than conventional methods. Typical exposure dose conditions for the conventional methods (e.g., >25 mJ/cm²) to provide sufficient acid generation in the overcoat may often suffer the undesired photoreaction in the photoresist mandrels 220. Addressing this issue, the exposure dose in various embodiments of the methods may be between 1 mJ/cm² and 25 mJ/cm².

In response to the exposure to the actinic radiation 115, the photo-acid generator (PAG) 312 may generate a photo acid in the first overcoat 310, and the photo acid may trigger the acid amplification. The acid amplifier (AA) 314 may be decomposed autocatalytically and generate more acid, increasing the acid content in the exposed region of the first overcoat 310. Once the acid content reaches a certain level, the generated acid in the first overcoat 310 may be able to diffuse into the photoresist mandrels 220 (i.e., diffusing acid 325 in FIGS. 1E and 1F). As indicated by arrows, the diffusing acid 325 may diffuse laterally into the first overcoat 310 through the interface between the photoresist mandrel 220 and the first overcoat 310. The diffusing acid 325 may then induce a chemical reaction to change the solubility of the reacted portion of the photoresist mandrels 220. As a result, acid-reacted layers 320 may be formed from the photoresist mandrel 220 on their sidewalls. The acid-reacted layers 320 may be the antispacers (i.e., sacrificial structure) that will be selectively removed by a subsequent process (e.g., development step) to form sub-resolution recess/trench features. In various embodiments, the sub-resolution recess/trench features may comprise a width between 1 nm and 15 nm.

The solubility of the acid-reacted layers 320 is higher in one or more developing solvents (e.g., an aqueous TMAH solution) than the remaining unreacted portion of the photoresist mandrels 220. In one or more embodiments, where the layer of the first overcoat 310 covers the top surface of the photoresist mandrels 220, the acid-reacted layers 320 may further comprise a lateral portion formed over the top surface of the photoresist mandrels 220.

The thickness of the acid-reacted layers 320 may depend on the diffusivity of the diffusing acid 325. Accordingly, the molecular weight of the PAG 312 and the AA 314 may be selected based on a desired diffusivity of the acid at a particular temperature. A process temperature may also be controlled to achieve the desired thickness of the acid-reacted layers 320.

In various embodiments, the acid diffusion may immediately occur in response to the exposure step. In one or more embodiments, a bake treatment may optionally be performed to initiate or accelerate the acid diffusion following the exposure step.

FIG. 1G illustrates a cross-sectional view of the substrate 110 after removing the first overcoat 310, and FIG. 1H illustrates a corresponding top view of the substrate 110.

In various embodiments, the first overcoat 310 may be removed by a wet process using a solution that dissolves the first overcoat 310. In certain embodiments, a solvent of 4-methyl-2-pentanol or 14iisoamyl ether may be used. After the removal step, the top surfaces of the intermediate layer 210 and the photoresist mandrels 220 become visible again in the top view as illustrated in FIG. 1H.

FIG. 1I illustrates a cross-sectional view of the substrate after depositing a second overcoat 410, and FIG. 1J illustrates a corresponding top view of the substrate 110.

In various embodiments, the second overcoat 410 may be deposited using a coating process or a spin-on process. In FIGS. 1C and 1D, the second overcoat 410 covers the top surface of the photoresist mandrel 220 in addition to their sidewalls. In various embodiments, the second overcoat 410 may comprise a polymer material.

In certain embodiments, an overcoat bake treatment may be performed after depositing the second overcoat 410 and prior to a subsequent development step (e.g., FIGS. 1K and 1L). In one embodiment, the overcoat bake may be performed by thermally treating the substrate 110, for example, at 80-140° C.

FIG. 1K illustrates a cross-sectional view of the substrate 110 after a development step, and FIG. 1L illustrates a corresponding top view of the substrate 110.

In FIGS. 1K and 1L, the substrate 110 may be treated by a developing solvent by a conventional developing method. In certain embodiments, the developing solvent may comprise an aqueous solution of tetramethylammonium hydroxide (TMAH), but other solvents may be used in other embodiments. After developing, the acid-reacted layers 320 are selectively removed, forming trenches 420 as an antispacer pattern between the sidewalls of the photoresist mandrel 220 and the second overcoat 410. The developing solvent may be selected to have a selectivity to the photoresist mandrel 220 and the second overcoat 410. In FIG. 1L, a portion of the intermediate layer 210 becomes visible through the trenches 420.

FIG. 1M illustrates a cross-sectional view of the substrate 110 after a pattern transfer, and FIG. 1N illustrates a corresponding top view of the substrate 110.

In FIGS. 1M and 1N, the intermediate layer 210 may be etched by an anisotropic etching process, such as reactive ion etch (RIE). The anisotropic etching process transfers the anti-spacer pattern (the trenches 420) to the intermediate layer 210. In various embodiments, the transferred pattern may be used to form a contact hole, a via, a metal line, gate line, isolation region, and other features useful in semiconductor fabrication.

As described above, the feature pitch defined by the antispacers is smaller than the initial pitch defined by the mandrel pattern, thereby increasing the feature density. In certain embodiments, critical dimensions (CD) of the photoresist mandrel and antispacers (defined by the acid diffusion length) may be selected such that a resulting feature pitch for a line-space-line-space pattern is 1:1:1:1; however, this disclosure contemplates other feature pitches.

FIG. 2 illustrates a top view of another substrate after the exposure to the actinic radiation and removing the first overcoat in accordance with alternate embodiments.

In prior embodiments described above, the exposure step is performed using a photomask to provide a pattern of an actinic radiation (e.g., FIGS. 1E and 1F). In these embodiments, the acid formation and diffusion starts in the selected area in the first overcoat, and this method may be referred to as photoselective acid diffusion because the acid diffusion into the photoresist mandrel may be limited to the proximity of the exposed area. The photoselective method may advantageously enable the direct formation of recess features for slot contacts.

In alternate embodiments, the methods may be applied for non-photoselective acid diffusion, where the exposure step is performed without a photomask to treat the entirety of the substrate or the first overcoat (i.e., blanket exposure). The top view of an example resulting structure after the exposure step and the first overcoat removal is illustrated in FIG. 2. The initial substrate structure and the process flows except the exposure step may be identical to those in FIGS. 1A-IN, and thus will not be repeated. In FIG. 2, the acid formation and diffusion may occur across the entire are of the first overcoat, and the acid-reacted layers 320 may thereby be formed along the entire length of the photoresist mandrels 220. The non-photoselective method can therefore form long trench features, which may be cut into segments by performing additional patterning processes (e.g., cutting).

FIG. 3 illustrates the effect of the presence of an acid amplifier (AA) in an overcoat on the development after a low-dose ultraviolet (UV) irradiation.

To examine the applicability of the combined use of photo-acid generator (PAG) and acid amplifier (AA) in the overcoat, the inventors of this application conducted blanket bilayer studies. The photoresist removal by the development solution was compared for different compositions: photoresist with PAG+AA overcoat, photoresist with PAG-only overcoat, and photoresist only (no overcoat). The photolithographic exposure was undertaken with a 266 nm laser exposing a dose stripe across the test wafer substrate in which high absorptivity of the photoresist results in majority of the impinging photons being absorbed within the upper layers of the photoresist film. This phenomenon results in a top-down dissolution of the resist film allowing for an assessment of the relative amounts of acid deprotection occurring within the resist due to exposure versus acid diffusion from the overcoat.

As illustrated in FIG. 3, exposure of a 1-25 mJ/cm² dose stripe across the bilayer samples produced significantly different reaction responses. Even at the dose close to 25 mJ/cm², the material removal in the photoresist only sample after post-exposure bake and develop was small at approximately 5 nm of thickness. Exposure of the bilayer containing the PAG only overcoat resulted in only a few additional nanometers of resist film thickness loss at 25 mJ/cm². Comparatively, exposure of the PAG+AA overcoat sample exhibited >500% increased film thickness loss and therefore acid diffusion capability at 25 mJ/cm². Additionally, at low exposure doses <5 mJ/cm², extensive film thickness loss is observed in the PAG+AA system. The results of this comparative study demonstrate a relatively low exposure dose may produce a sufficient amount of acid to form antispacers in the photoresist film thanks to AA and its autocatalytic acid amplification.

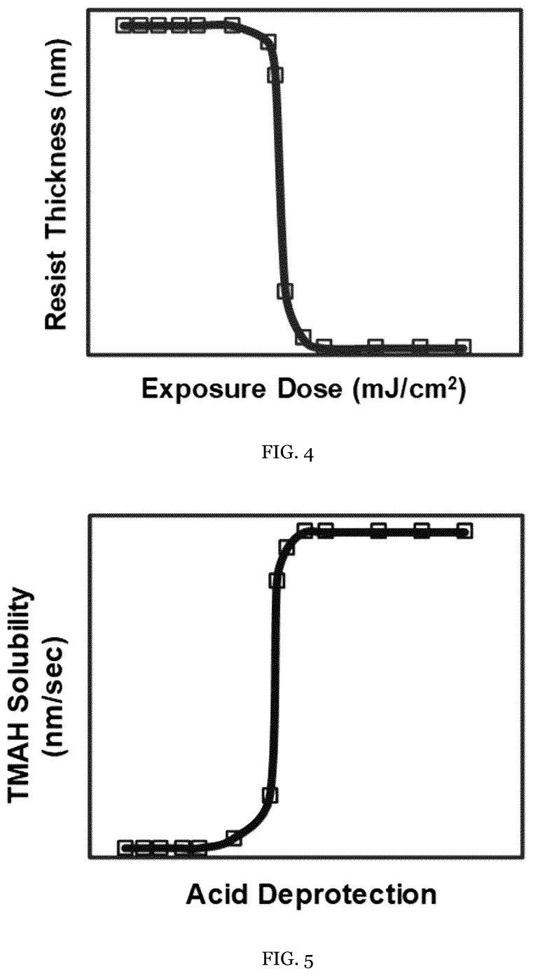

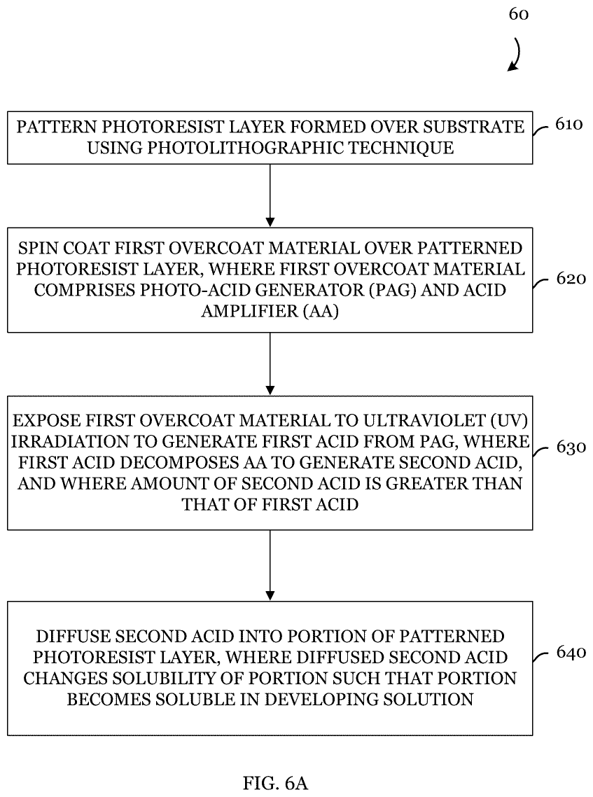

FIG. 4 illustrates the removal of a photoresist film as a function of exposure dose. FIG. 5 illustrates the solubility of a photoresist film as a function of the degree of acid deprotection controlled by exposure dose.

As described previously, minimizing the exposure dose required to generate the necessary local acid concentration within the overcoat maximizes the process window to prevent complete solubilization of the photoresist mandrel from homogenous deprotection due to PAG decomposition. FIGS. 4 and 5 illustrates experimental data for photoresist sensitivity and solubilization kinetics with regards to resin deprotection due to catalytic acid reaction, where critical thresholds of exposure dose for photoresist film loss and acid deprotection for solubility are shown, respectively. A lower exposure dose below the threshold can result in fewer PAG molecules within the photoresist mandrel decomposing to make acid capable of deprotecting the resist, which in turn minimizes or eliminates undesired solubilization of the photoresist mandrel. On the other hand, at a higher exposure dose, if the critical deprotection threshold is reached within the bulk of the photoresist mandrel, then complete solubilization will occur resulting in process failure. Accordingly, various embodiments of methods can apply the exposure step with an exposure dose below these thresholds.

FIG. 6A-6C illustrate process flow charts of methods of sub-resolution features comprising antispacer patterning in accordance with various embodiments. Example process flows follow in accordance with the embodiments already described above referring to FIGS. 1A-IN, and therefore the details will not be repeated.

In FIG. 6A, an example process flow 60 starts with patterning a photoresist layer formed over the substrate using a photolithographic technique (block 610, FIGS. 1A and 1B), followed by spin coating a first overcoat material over the patterned photoresist layer, where the first overcoat material comprises a photo-acid generator (PAG) and an acid amplifier (AA) (block 620, FIGS. 1C and 1D). Subsequently, the first overcoat material may be exposed to an ultraviolet (UV) irradiation to generate first acid from the PAG, where the first acid decomposes the AA to generate second acid, and where the amount of the second acid is greater than the amount of first acid (block 630, FIGS. 1E and 1F). The second acid may then diffuse into a portion of the patterned photoresist layer and change a solubility of the portion such that the portion becomes soluble in a developing solution (block 640).

In FIG. 6B, another example process flow 62 starts with forming a mandrel over a substrate (block 612, FIGS. 1A and 1B), followed by depositing a first overcoat material over the mandrel, where the first overcoat material comprises an acid-generator (AG) and an acid amplifier (AA), and where a concentration of the AA is greater than that of the AG (block 622, FIGS. 1C and 1D). A first acid may be generated from the AG and catalyze a formation of second acid from the AA, where the second acid diffuses into a portion of the mandrel (block 632, FIGS. 1E and 1F). Subsequently, the first overcoat material may be selectively removed (block 652, FIGS. 1G and 1H), and then a second overcoat material may be deposited over the mandrel (block 653, FIGS. 1I and 1J). After the deposition of the second overcoat material, two antispacers may be formed from the mandrel by selectively removing the portion of the mandrel, where each antispacer is formed on each sidewall of the mandrel and the antispacers separate the mandrel and the second overcoat material (block 662, FIGS. 1K and 1L).

In FIG. 6C, yet another process flow 64 starts with patterning a photoresist layer formed over the substrate using a deep ultraviolet (DUV) photolithographic technique (block 614, FIGS. 1A and 1B), followed by spin coating a first overcoat material over the patterned photoresist layer, where the first overcoat material comprises a photo-acid generator (PAG) and an acid amplifier (AA) (block 620, FIGS. 1C and 1D). Subsequently, the first overcoat material may be exposed to an ultraviolet (UV) irradiation to generate first acid from the PAG, where the first acid decomposes the AA to generate second acid and the second acid diffuses into a portion of the patterned photoresist layer (block 634, FIGS. 1E and 1F). The first overcoat material may be selectively removed (block 652, FIGS. 1G and 1H), and then a second overcoat material may be spin coated over the patterned photoresist layer (block 655, FIGS. 11 and 1J). The second overcoat material may then be etched back to expose a top surface of the patterned photoresist layer (block 656), followed by selectively dissolving and removing the portion of the patterned photoresist layer using a developing solution to form a relief pattern that has a pitch size below an optical resolution of the DUV photolithographic technique (block 664, FIGS. 1K and 1L).

Example embodiments of the invention are described below. Other embodiments can also be understood from the entirety of the specification as well as the claims filed herein.

Example 1. A method of processing a substrate includes the patterning a photoresist layer formed over the substrate using a photolithographic technique, and spin coating a first overcoat material over the patterned photoresist layer, where the first overcoat material includes a photo-acid generator (PAG) and an acid amplifier (AA). The method includes exposing the first overcoat material to an ultraviolet (UV) irradiation to generate first acid from the PAG, where the first acid decomposes the AA to generate second acid, and a total amount of the second acid generated from the decomposition of the AA being greater than a total amount of first acid generated from the PAG. The method includes diffusing the second acid into a portion of the patterned photoresist layer, where the diffused second acid changes a solubility of the portion such that the portion becomes soluble in a developing solution.

Example 2. The method of example 1, further includes after the diffusing, selectively removing the first overcoat material; after the removing, spin coating a second overcoat material over the patterned photoresist layer; etching back the second overcoat material to expose a top surface of the patterned photoresist layer; and using the developing solution, selectively removing the portion of the patterned photoresist layer to form a recess defined by a remaining portion of the photoresist layer and the second overcoat material.

Example 3. The method of one of examples 1 or 2, where the etching back including treating the substrate with the developing solution.

Example 4. The method of one of examples 1 to 3, where the recess has a width between 1 nm and 15 nm.

Example 5. The method of one of examples 1 to 4, where the photolithographic technique uses deep UV light (DUV) and the recess has a critical dimension below an optical resolution of the photolithographic technique.

Example 6. The method of one of examples 1 to 5, further includes after the exposing, a post-exposure bake treatment.

Example 7. The method of one of examples 1 to 6, where the exposing to the UV irradiation is performed with a dose between 1 and 25 mJ/cm².

Example 8. The method of one of examples 1 to 7, where the exposing to the UV irradiation is performed using a photomask.

Example 9. The method of one of examples 1 to 8, further includes selecting concentrations of the PAG and the AA in the first overcoat material based on a target acid concentration and a dose for the exposing.

Example 10. A method of patterning includes forming a mandrel over a substrate, and depositing a first overcoat material over the mandrel. The first overcoat material includes an acid-generator (AG) and an acid amplifier (AA), where a concentration of the AA is greater than that of the AG. The method includes generating first acid from the AG, the first acid catalyzing a formation of second acid from the AA, the second acid diffusing into a portion of the mandrel. The method includes selectively removing the first overcoat material, and depositing a second overcoat material over the mandrel, and forming two antispacers from the mandrel by selectively removing the portion of the mandrel, where each antispacer is formed on each sidewall of the mandrel, the antispacers separating the mandrel and the second overcoat material.

Example 11. The method of example 10, where the generating of the first acid including exposing the substrate to an actinic radiation, and where the AG includes a photo-acid generator (PAG) that generates the first acid in response to exposure to the actinic radiation.

Example 12. The method of one of examples 10 or 11, where the PAG includes an ionic PAG, non-ionic PAG, or polymer bound PAG.

Example 13. The method of one of examples 10 to 12, where the AA includes 3-hydroxy-3-methylbutyl 4-methylbenzenesulfonate, 3-Hydroxy-3-methylbutyl 4-(trifluoromethyl)benzenesulfonate, or 3-Hydroxybutyl 4-(trifluoromethyl)benzenesulfonate.

Example 14. The method of one of examples 10 to 13, where selectively removing the portion of the mandrel includes treating the substrate with a developing solution, where the developing solution dissolves only the portion of the mandrel selectively to a remaining portion of the mandrel.

Example 15. The method of one of examples 10 to 14, where the developing solution includes an aqueous solution of tetramethyl ammonium hydroxide (TMAH).

Example 16. A method of processing a substrate includes patterning a photoresist layer formed over the substrate using a deep ultraviolet (DUV) photolithographic technique; and spin coating a first overcoat material over the patterned photoresist layer, where the first overcoat material includes a photo-acid generator (PAG) and an acid amplifier (AA). The method includes exposing the first overcoat material to an ultraviolet (UV) irradiation to generate first acid from the PAG, the first acid decomposing the AA to generate second acid, where the second acid diffuses into a portion of the patterned photoresist layer. The method includes selectively removing the first overcoat material, spin coating a second overcoat material over the patterned photoresist layer, etching back the second overcoat material to expose a top surface of the patterned photoresist layer, and selectively dissolving and removing the portion of the patterned photoresist layer using a developing solution to form a relief pattern that has a pitch size below an optical resolution of the DUV photolithographic technique.

Example 17. The method of example 16, where a concentration of the PAG in the first overcoat material is between 0.1% and 4%, and that of the AA is between 1% and 20%.

Example 18. The method of one of examples 16 or 17, where the AA includes a sulfonate that releases sulfonic acid when decomposing.

Example 19. The method of one of examples 16 to 18, where the second acid includes fluorinated sulfonic acid.

Example 20. The method of one of examples 16 to 19, where the portion of the patterned photoresist layer becomes solution in the developing solution due to the second acid diffused into the portion, and where a dose of exposure to the UV irradiation is such that the patterned photoresist layer does not react in response to the UV irradiation.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
patterning a photoresist layer formed over the substrate using a photolithographic technique;
spin coating a first overcoat material over the patterned photoresist layer, the first overcoat material comprising a photo-acid generator (PAG) and an acid amplifier (AA);
exposing the first overcoat material to an ultraviolet (UV) irradiation to generate first acid from the PAG, the first acid decomposing the AA to generate second acid, a total amount of the second acid generated from the decomposition of the AA being greater than a total amount of first acid generated from the PAG; and
diffusing the second acid into a portion of the patterned photoresist layer, the diffused second acid changing a solubility of the portion such that the portion becomes soluble in a developing solution.

2. The method of claim 1, further comprising:
after the diffusing, selectively removing the first overcoat material;
after the removing, spin coating a second overcoat material over the patterned photoresist layer;
etching back the second overcoat material to expose a top surface of the patterned photoresist layer; and
using the developing solution, selectively removing the portion of the patterned photoresist layer to form a recess defined by a remaining portion of the photoresist layer and the second overcoat material.

3. The method of claim 2, wherein the etching back comprising treating the substrate with the developing solution.

4. The method of claim 2, wherein the recess has a width between 1 nm and 15 nm.

5. The method of claim 2, wherein the photolithographic technique uses deep UV light (DUV) and the recess has a critical dimension below an optical resolution of the photolithographic technique.

6. The method of claim 1, further comprising, after the exposing, a post-exposure bake treatment.

7. The method of claim 1, wherein the exposing to the UV irradiation is performed with a dose between 1 and 25 mJ/cm².

8. The method of claim 1, wherein the exposing to the UV irradiation is performed using a photomask.

9. The method of claim 1, further comprising selecting concentrations of the PAG and the AA in the first overcoat material based on a target acid concentration and a dose for the exposing.

10. A method of patterning, the method comprising:
forming a mandrel over a substrate;
depositing a first overcoat material over the mandrel, the first overcoat material comprising an acid-generator (AG) and an acid amplifier (AA), a concentration of the AA being greater than that of the AG;
generating first acid from the AG, the first acid catalyzing a formation of second acid from the AA, the second acid diffusing into a portion of the mandrel;
selectively removing the first overcoat material;
depositing a second overcoat material over the mandrel; and
forming two antispacers from the mandrel by selectively removing the portion of the mandrel, each antispacer being formed on each sidewall of the mandrel, the antispacers separating the mandrel and the second overcoat material.

11. The method of claim 10, wherein the generating of the first acid comprising exposing the substrate to an actinic radiation, and wherein the AG comprises a photo-acid generator (PAG) that generates the first acid in response to exposure to the actinic radiation.

12. The method of claim 11, wherein the PAG comprises an ionic PAG, non-ionic PAG, or polymer bound PAG.

13. The method of claim 10, wherein the AA comprises 3-hydroxy-3-methylbutyl 4-methylbenzenesulfonate, 3-Hydroxy-3-methylbutyl 4-(trifluoromethyl)benzenesulfonate, or 3-Hydroxybutyl 4-(trifluoromethyl)benzenesulfonate.

14. The method of claim 10, wherein selectively removing the portion of the mandrel comprises treating the substrate with a developing solution, wherein the developing solution dissolves only the portion of the mandrel selectively to a remaining portion of the mandrel.

15. The method of claim 14, wherein the developing solution comprises an aqueous solution of tetramethyl ammonium hydroxide (TMAH).

16. A method of processing a substrate, the method comprising:
patterning a photoresist layer formed over the substrate using a deep ultraviolet (DUV) photolithographic technique;
spin coating a first overcoat material over the patterned photoresist layer, the first overcoat material comprising a photo-acid generator (PAG) and an acid amplifier (AA); and
exposing the first overcoat material to an ultraviolet (UV) irradiation to generate first acid from the PAG, the first acid decomposing the AA to generate second acid, the second acid diffusing into a portion of the patterned photoresist layer;
selectively removing the first overcoat material;
spin coating a second overcoat material over the patterned photoresist layer;
etching back the second overcoat material to expose a top surface of the patterned photoresist layer; and
selectively dissolving and removing the portion of the patterned photoresist layer using a developing solution to form a relief pattern that has a pitch size below an optical resolution of the DUV photolithographic technique.

17. The method of claim 16, wherein a concentration of the PAG in the first overcoat material is between 0.1% and 4%, and that of the AA is between 1% and 20%.

18. The method of claim 16, wherein the AA comprises a sulfonate that releases sulfonic acid when decomposing.

19. The method of claim 16, wherein the second acid comprises fluorinated sulfonic acid.

20. The method of claim 16, wherein the portion of the patterned photoresist layer becomes solution in the developing solution due to the second acid diffused into the portion, and wherein a dose of exposure to the UV irradiation is such that the patterned photoresist layer does not react in response to the UV irradiation.
